(19) United States
(12) Patent Application Publication
(10) Pub. No.: US 2025/0329932 A1
(43) Pub. Date: Oct. 23, 2025

(54) MULTILAYER SUBSTRATE

(71) Applicant: Murata Manufacturing Co., Ltd., Nagaokakyo-shi (JP)

(72) Inventor: Kentaro KAWABE, Nagaokakyo-shi (JP)

(21) Appl. No.: 19/256,811

(22) Filed: Jul. 1, 2025

Related U.S. Application Data
(63) Continuation of application No. PCT/JP2023/042580, filed on Nov. 28, 2023.

(30) Foreign Application Priority Data
Jan. 11, 2023 (JP) 2023-002194

(51) Int. Cl. H01Q 9/04; H01Q 1/48

(52) U.S. Cl. CPC H01Q 9/0414; H01Q 1/48

(57) ABSTRACT

A multilayer substrate includes a first ground conductor layer overlapping a radiation conductor layer when viewed in a negative direction of the Z-axis and extending in the negative direction of the Z-axis from the radiation conductor layer, and second ground conductor layers not overlapping the radiation conductor layer and extending in a positive direction of the Z-axis from the first ground conductor layer. No ground conductor layer other than the first ground conductor layer is located between the radiation conductor layer and the second ground conductor layers. An electric current path is connected to the radiation conductor layer. A branched conductor layer extends in the negative direction of the Z-axis from the second ground conductor layers, and extends away from the electric current path. At least a portion of the branched conductor layer overlaps the second ground conductor layers.

### CROSS REFERENCE TO RELATED APPLICATIONS

This application claims the benefit of priority to Japanese Patent Application No. 2023-002194 filed on Jan. 11, 2023 and is a Continuation Application of PCT Application No. PCT/JP2023/042580 filed on Nov. 28, 2023. The entire contents of each application are hereby incorporated herein by reference.

### BACKGROUND OF THE INVENTION

### 1. Field of the Invention

The present invention relates to multilayer substrates.

### 2. Description of the Related Art

As an example of an existing multilayer substrate, an antenna module described in International Publication No. 2020/145392 is known. This antenna module includes a ground electrode, a feed element, a feeding wire, and a first stub. The ground electrode and the feed element form a patch antenna. The feeding wire transmits a high-frequency signal to a first feeding point of the feed element. The first stub is diverged from the feeding wire.

The antenna module described in International Publication No. 2020/145392 is intended to reduce coupling between the first stub and the feed element.

### SUMMARY OF THE INVENTION

Example embodiments of the present invention provide multilayer substrates that each reduce coupling between a branched conductor layer and a radiation conductor layer.

A multilayer substrate according to an example embodiment of the present invention includes a multilayer body, a radiation conductor layer, a first ground conductor layer, a second ground conductor layer, an electric current path, and a branched conductor layer, wherein the multilayer body includes a plurality of insulator layers laminated along a Z-axis, the radiation conductor layer is in or on the multilayer body, the first ground conductor layer is in or on the multilayer body, overlaps the radiation conductor layer when viewed in a negative direction of the Z-axis, and extends in the negative direction of the Z-axis from the radiation conductor layer, the second ground conductor layer is in or on the multilayer body, does not overlap the radiation conductor layer when viewed in the negative direction of the Z-axis, and extends in a positive direction of the Z-axis from the first ground conductor layer, when viewed in the negative direction of the Z-axis, no ground conductor layer other than the first ground conductor layer is between the radiation conductor layer and the second ground conductor layer, the electric current path is provided in or on the multilayer body, and connected to the radiation conductor layer, the branched conductor layer is provided in or on the multilayer body, extends in the negative direction of the Z-axis from the second ground conductor layer, and extends away from the electric current path, and, when viewed in the negative direction of the Z-axis, at least a portion of the branched conductor layer overlaps the second ground conductor layer.

Multilayer substrates according to example embodiments of the present invention each reduce coupling between a branched conductor layer and a radiation conductor layer.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is an exploded perspective view of a multilayer substrate 10 according to an example embodiment of the present invention.

FIG. 2 is an exploded perspective view of a multilayer substrate 10a according to an example embodiment of the present invention.

FIG. 3 is an exploded perspective view of a multilayer substrate 10b according to an example embodiment of the present invention.

FIG. 4 is an exploded perspective view of a multilayer substrate 10c according to an example embodiment of the present invention.

FIG. 5 is an exploded perspective view of a multilayer substrate 10d according to an example embodiment of the present invention.

FIG. 6 is a rear view of the multilayer substrate 10d in FIG. 5.

### DETAILED DESCRIPTION OF THE EXAMPLE EMBODIMENTS

Example embodiments of the present invention will be described in detail below with reference to the drawings.

### EXAMPLE EMBODIMENTS

### Structure of Multilayer Substrate 10

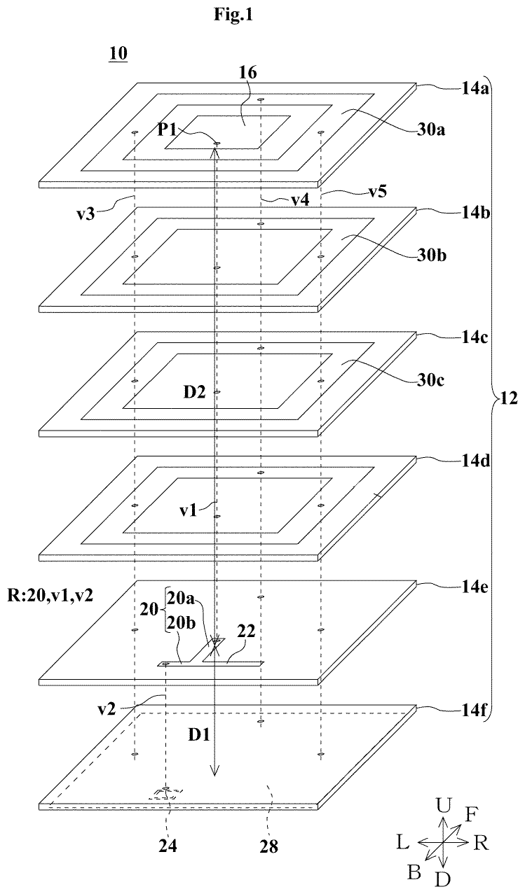

Hereafter, a structure of a multilayer substrate 10 according to an example embodiment of the present invention is described below with reference to the drawings. FIG. 1 is an exploded perspective view of the multilayer substrate 10.

In the description below, the lamination direction of a multilayer body 12 is parallel or substantially parallel to the vertical axis. The vertical axis matches a Z-axis. The upward direction is a positive direction of the Z-axis. The downward direction is a negative direction of the Z-axis. When the multilayer body 12 is viewed in the downward direction, two sides of the multilayer body 12 extend in the lateral axis. When the multilayer body 12 is viewed in the downward direction, the remaining two sides of the multilayer body 12 extend in the front-rear axis. The lateral axis is orthogonal or substantially orthogonal to the vertical axis. The front-rear axis is orthogonal or substantially orthogonal to the vertical axis and the lateral axis. The directions herein are defined as examples. Thus, the directions during actual use of the multilayer substrate 10 do not have to match the direction herein.

The multilayer substrate 10 is included in, for example, a wireless communication terminal such as a smartphone. As illustrated in FIG. 1, the multilayer substrate 10 includes a multilayer body 12, a radiation conductor layer 16, a first ground conductor layer 28, second ground conductor layers 30a to 30d, an electric current path R, and a branched conductor layer 22.

The multilayer body 12 has a plate shape. As illustrated in FIG. 1, the multilayer body 12 has a rectangular or substantially rectangular shape when viewed in the downward direction. The multilayer body 12 includes insulator layers 14a to 14f that are laminated along the vertical axis (the Z-axis). The insulator layers 14a to 14f are arranged in this order from the top to the bottom. The material of the insulator layers 14a to 14f is a thermoplastic resin such as, for example, polyimide or liquid crystal polymer. The insulator layers 14a to 14f are each fused with its adjacent ones. The multilayer body 12 has flexibility.

The radiation conductor layer 16 radiates and/or receives high-frequency signals. The radiation conductor layer 16 is disposed in or on the multilayer body 12. In the present example embodiment, the radiation conductor layer 16 is located at an upper main surface of the insulator layer 14a. As illustrated in FIG. 1, the radiation conductor layer 16 has a rectangular or substantially rectangular shape when viewed in the downward direction. As illustrated in FIG. 1, when viewed in the downward direction, the radiation conductor layer 16 includes two sides extending along the front-rear axis and two sides extending along the lateral axis.

As illustrated in FIG. 1, the first ground conductor layer 28 is disposed in or on the multilayer body 12. More specifically, the first ground conductor layer 28 is located below (in the negative direction of the Z-axis from) the radiation conductor layer 16. The first ground conductor layer 28 is located at a lower main surface of the insulator layer 14f. As illustrated in FIG. 1, when viewed in the downward direction, the first ground conductor layer 28 has a rectangular or substantially rectangular shape. The first ground conductor layer 28 covers the entirety or substantially the entirety of the lower main surface of the insulator layer 14f. Thus, when viewed in the downward direction (the negative direction of the Z-axis), the first ground conductor layer 28 overlaps the radiation conductor layer 16. The first ground conductor layer 28 is connected to a ground potential. Thus, the radiation conductor layer 16 and the first ground conductor layer 28 define a patch antenna.

As illustrated in FIG. 1, the second ground conductor layers 30a to 30d are disposed in or on the multilayer body 12. More specifically, the second ground conductor layers 30a to 30d are located above (in the positive direction of the Z-axis from) the first ground conductor layer 28. In the present example embodiment, each of the second ground conductor layers 30a to 30d is located at the upper main surface of the corresponding one of the insulator layers 14a to 14d.

When viewed in the downward direction (the negative direction of the Z-axis), the second ground conductor layers 30a to 30d each have a loop shape surrounding the radiation conductor layer 16. The outer edge and the inner edge of each of the second ground conductor layers 30a to 30d have a rectangular or substantially rectangular shape including two sides extending along the front-rear axis and two sides extending along the lateral axis. Thus, the second ground conductor layers 30a to 30d do not overlap the radiation conductor layer 16 when viewed in the downward direction (the negative direction of the Z-axis).

However, when viewed in the downward direction, the second ground conductor layers 30a to 30d are located near the radiation conductor layer 16. More specifically, when viewed in the downward direction (the negative direction of the Z-axis), no ground conductor layer other than the first ground conductor layer 28 is located between the radiation conductor layer 16 and the second ground conductor layers 30a to 30d. The second ground conductor layers 30a to 30d are connected to the ground potential.

A high-frequency signal is transmitted to the electric current path R. The electric current path R is defined by a conductor that connects an external electrode 24 and the radiation conductor layer 16. The electric current path R is disposed in or on the multilayer body 12. The electric current path R is connected to the radiation conductor layer 16. The electric current path R includes a signal conductor layer 20 and inter-layer connection conductors v1 and v2.

The signal conductor layer 20 is disposed in or on the multilayer body 12. The signal conductor layer 20 is located below (in the negative direction of the Z-axis from) the radiation conductor layer 16. The signal conductor layer 20 is located above (in the positive direction of the Z-axis from) the first ground conductor layer 28. In the present example embodiment, the signal conductor layer 20 is located at the upper main surface of the insulator layer 14e. Thus, a distance D1 between the signal conductor layer 20 and the first ground conductor layer 28 along the vertical axis (the Z-axis) is shorter than a distance D2 between the signal conductor layer 20 and the radiation conductor layer 16 along the vertical axis (the Z-axis).

The signal conductor layer 20 includes a first portion 20a and a second portion 20b. The first portion 20a extends in the front-rear axis. The second portion 20b extends in the lateral axis. When viewed in the downward direction, the front end portion of the first portion 20a overlaps the radiation conductor layer 16. The rear end portion of the first portion 20a is connected to a right end portion of the second portion 20b.

As illustrated in FIG. 1, the external electrode 24 is located at a lower main surface of the insulator layer 14f. The external electrode 24 is not in contact with the first ground conductor layer 28. Thus, the external electrode 24 is located in an opening in the first ground conductor layer 28. When viewed in the downward direction, the external electrode 24 overlaps a left end portion of the second portion. A high-frequency signal is input into or output from the external electrode 24.

The inter-layer connection conductor v1 electrically connects the radiation conductor layer 16 and the signal conductor layer 20 to each other. More specifically, the inter-layer connection conductor v1 extends through the insulator layers 14a to 14d along the vertical axis. The upper end of the inter-layer connection conductor v1 is in contact with the radiation conductor layer 16 at a feeding point P1. The lower end of the inter-layer connection conductor v1 is in contact with the front end portion of the first portion 20a.

The inter-layer connection conductor v2 electrically connects the signal conductor layer 20 and the external electrode 24 to each other. More specifically, the inter-layer connection conductor v2 extends through the insulator layers 14e and 14f along the vertical axis. The upper end of the inter-layer connection conductor v2 is in contact with the left end portion of the second portion 20b. The lower end of the inter-layer connection conductor v2 is in contact with the external electrode 24.

Inter-layer connection conductors v3 to v5 electrically connect the first ground conductor layer 28 and the second ground conductor layers 30a to 30d to one another. More specifically, the inter-layer connection conductors v3 to v5 extend through the insulator layers 14a to 14f along the vertical axis. The upper ends of the inter-layer connection conductors v3 to v5 are in contact with the second ground conductor layer 30a. The lower ends of the inter-layer connection conductors v3 to v5 are in contact with the first ground conductor layer 28. Furthermore, the middle portions of the inter-layer connection conductors v3 to v5 are in contact with the second ground conductor layers 30b to 30d.

The branched conductor layer 22 is disposed in or on the multilayer body 12. The branched conductor layer 22 is located below (in the negative direction of the Z-axis from) the second ground conductor layers 30a to 30d. In the present example embodiment, the branched conductor layer 22 is located at the upper main surface of the insulator layer 14e. The branched conductor layer 22 extends away from the electric current path R. More specifically, the branched conductor layer 22 extends rightward from the rear end portion of the first portion 20a and the right end portion of the second portion 20b. Thus, when viewed in the downward direction, the branched conductor layer 22 has a linear shape. When viewed in the downward direction (the negative direction of the Z-axis), at least a portion of the branched conductor layer 22 overlaps the second ground conductor layers 30a to 30d. In the present example embodiment, when viewed in the downward direction, the entirety or substantially the entirety of the branched conductor layer 22 overlaps the second ground conductor layers 30a to 30d. Thus, when viewed in the downward direction (the negative direction of the Z-axis), a connection portion at which the branched conductor layer 22 and the electric current path R are connected overlaps the second ground conductor layers 30a to 30d. However, when viewed in the downward direction (the negative direction of the Z-axis), the branched conductor layer 22 does not overlap the radiation conductor layer 16. The branched conductor layer 22 with this structure is an open stub. Thus, the branched conductor layer 22 is not connected to any conductor layer other than the signal conductor layer 20.

The radiation conductor layer 16, the signal conductor layer 20, the branched conductor layer 22, the external electrode 24, the first ground conductor layer 28, and the second ground conductor layers 30a to 30d described above are formed by, for example, patterning metal foil bonded to the upper main surfaces or the lower main surfaces of the insulator layers 14a to 14f. The metal foil is, for example, copper foil. The inter-layer connection conductors v1 to v5 are formed by, for example, filling through-holes extending through the insulator layers 14a to 14f along the vertical axis with a conductive paste, and solidifying the conductive paste with heat and pressure.

### Advantageous Effects

The multilayer substrate 10 can reduce coupling between the branched conductor layer 22 and the radiation conductor layer 16. More specifically, when viewed in the downward direction, at least a portion of the branched conductor layer 22 overlaps the second ground conductor layers 30a to 30d. Thus, the second ground conductor layers 30a to 30d are located between the radiation conductor layer 16 and the branched conductor layer 22. Thus, the multilayer substrate 10 can reduce coupling between the branched conductor layer 22 and the radiation conductor layer 16.

In the present example embodiment, when viewed in the downward direction, the connection portion at which the branched conductor layer 22 and the electric current path R are connected overlaps the second ground conductor layers 30a to 30d. This structure can thus more effectively reduce coupling between the branched conductor layer 22 and the radiation conductor layer 16.

In the present example embodiment, when viewed in the downward direction, the entirety or substantially the entirety of the branched conductor layer 22 overlaps the second ground conductor layers 30a to 30d. This structure can thus more effectively reduce coupling between the branched conductor layer 22 and the radiation conductor layer 16.

In the present example embodiment, when viewed in the downward direction, the branched conductor layer 22 does not overlap the radiation conductor layer 16. This structure can thus more effectively reduce coupling between the branched conductor layer 22 and the radiation conductor layer 16.

In the present example embodiment, the branched conductor layer 22 extends away from the electric current path R. Thus, the branched conductor layer 22 matches the characteristic impedance caused in the radiation conductor layer 16 with the characteristic impedance caused in the electric current path R. Thus, at the boundary between the radiation conductor layer 16 and the electric current path R, reflection of the high-frequency signal is reduced, and a loss of the high-frequency signal is reduced.

For the reason described below, the branched conductor layer 22 is preferably not spaced a long distance from the radiation conductor layer 16. At the feeding point P1, reflection of the high-frequency signal occurs. The reflected high-frequency signal is reflected again at the branched conductor layer 22. The reflected wave is radiated as an electromagnetic wave from the radiation conductor layer 16. Thus, in the multilayer substrate 10, the reflected wave is used as an electromagnetic wave of the high-frequency signal.

When the branched conductor layer 22 is spaced a long distance from the radiation conductor layer 16, the reflected wave causes a loss between the branched conductor layer 22 and the radiation conductor layer 16. Thus, the branched conductor layer 22 is preferably not spaced a long distance from the radiation conductor layer 16. This structure improves gains of the radiation conductor layer 16.

In the multilayer substrate 10, when viewed in the downward direction, the second ground conductor layers 30a to 30d do not overlap the radiation conductor layer 16, and are located above the first ground conductor layer 28. A radiation pattern and a reception pattern of the radiation conductor layer 16 are less likely to expand in a direction toward the first ground conductor layer 28. This structure improves directivity of the radiation pattern and the reception pattern of the radiation conductor layer 16.

In the present example embodiment, when viewed in the downward direction, the second ground conductor layers 30a to 30d each have a loop shape surrounding the radiation conductor layer 16. This structure further improves directivity of the radiation pattern and the reception pattern of the radiation conductor layer 16.

In the multilayer substrate 10, the distance D1 between the signal conductor layer 20 and the first ground conductor layer 28 along the vertical axis (the Z-axis) is shorter than the distance D2 between the signal conductor layer 20 and the radiation conductor layer 16 along the vertical axis (the Z-axis). This structure reduces coupling of the signal conductor layer 20 with the radiation conductor layer 16.

### First Modified Example

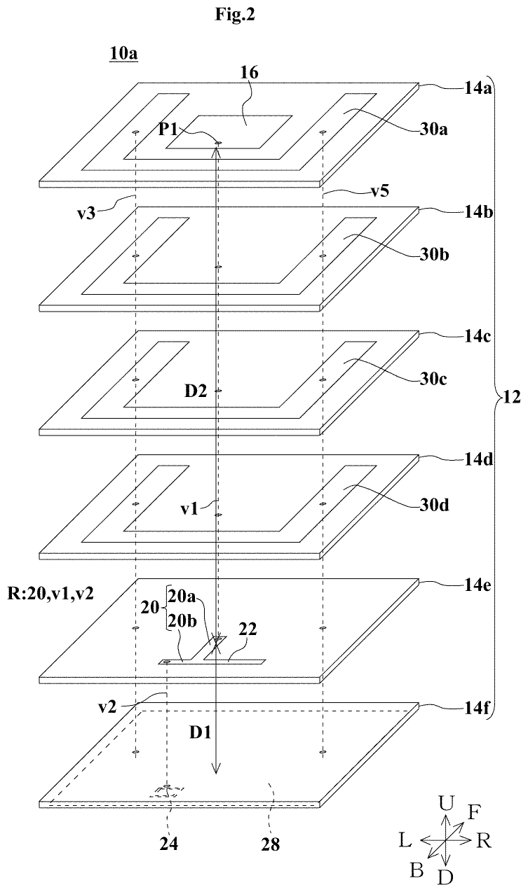

A multilayer substrate 10a according to a first modified example of an example embodiment of the present invention is described below with reference to a drawing. FIG. 2 is an exploded perspective view of the multilayer substrate 10a.

The multilayer substrate 10a differs from the multilayer substrate 10 in the shape of the second ground conductor layers 30a to 30d. More specifically, when viewed in the downward direction, the second ground conductor layers 30a to 30d have an angular-C shape. When viewed in the downward direction, each of the second ground conductor layers 30a to 30d does not include a front side. As in this structure, the second ground conductor layers 30a to 30d are not required to have a loop shape surrounding the radiation conductor layer 16 when viewed in the downward direction. Other components of the multilayer substrate 10a are the same or substantially the same as those of the multilayer substrate 10, and thus are not described. The multilayer substrate 10a has the same or substantially the same advantageous effects as the multilayer substrate 10.

### Second Modified Example

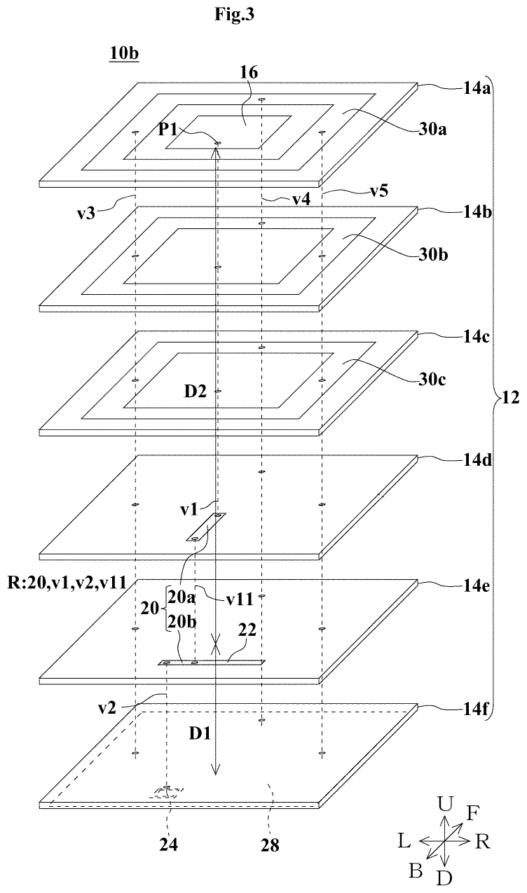

A multilayer substrate 10b according to a second modified example of an example embodiment of the present invention is described below with reference to a drawing. FIG. 3 is an exploded perspective view of the multilayer substrate 10b.

The multilayer substrate 10b differs from the multilayer substrate 10 in the following points.

The multilayer substrate 10b does not include the second ground conductor layer 30d.

The multilayer substrate 10b further includes an inter-layer connection conductor v11.

The first portion 20a and the second portion 20b are disposed on different insulator layers.

The first portion 20a is located at the upper main surface of the insulator layer 14d. The second portion 20b is located at the upper main surface of the insulator layer 14e. The inter-layer connection conductor v11 extends through the insulator layer 14d along the vertical axis (the Z-axis). The upper end of the inter-layer connection conductor v11 is in contact with the rear end portion of the first portion 20a. The lower end of the inter-layer connection conductor v11 is in contact with the right end portion of the second portion 20b and the left end portion of the branched conductor layer 22. Thus, the branched conductor layer 22 is connected to the inter-layer connection conductor v11. Other components of the multilayer substrate 10b are the same or substantially the same as those of the multilayer substrate 10, and thus are not described. The multilayer substrate 10b has the same or substantially the same advantageous effects as the multilayer substrate 10.

### Third Modified Example

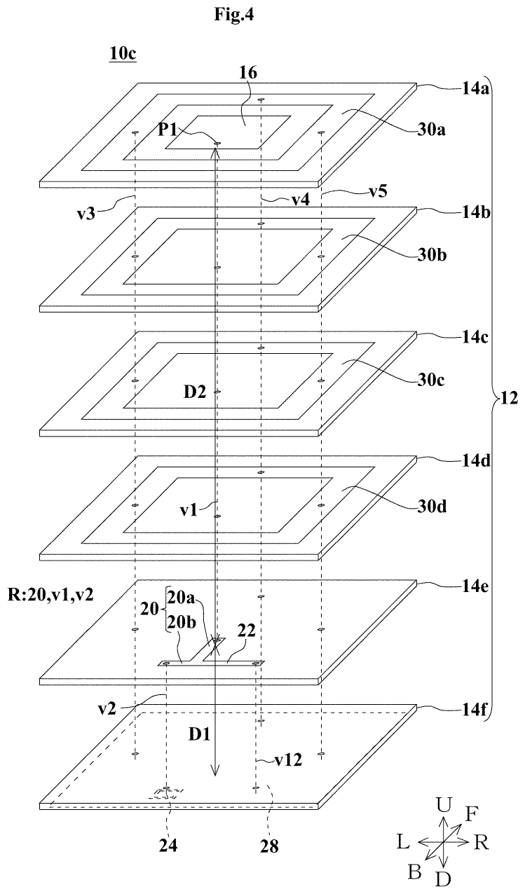

A multilayer substrate 10c according to a third modified example of an example embodiment of the present invention is described below with reference to a drawing. FIG. 4 is an exploded perspective view of the multilayer substrate 10c.

The multilayer substrate 10c differs from the multilayer substrate 10 in that the multilayer substrate 10c further includes an inter-layer connection conductor v12. The inter-layer connection conductor v12 electrically connects the branched conductor layer 22 and the first ground conductor layer 28 to each other. More specifically, the inter-layer connection conductor v12 extends through the insulator layers 14e and 14f along the vertical axis. The upper end of the inter-layer connection conductor v12 is in contact with the right end portion of the branched conductor layer 22. The lower end of the inter-layer connection conductor v12 is in contact with the first ground conductor layer 28. Thus, the branched conductor layer 22 with this structure is a short stub. Other components of the multilayer substrate 10c are the same or substantially the same as those of the multilayer substrate 10, and thus are not described. The multilayer substrate 10c has the same or substantially the same advantageous effects as the multilayer substrate 10.

### Fourth Modified Example

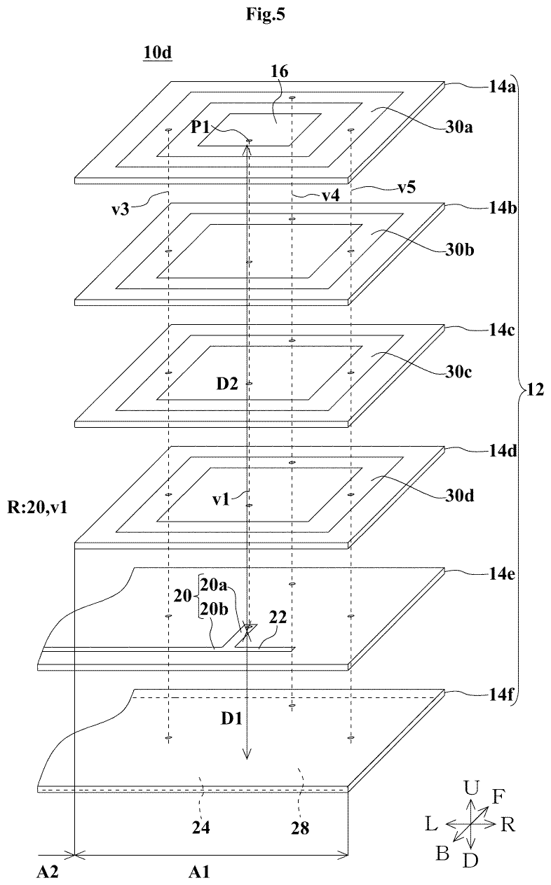

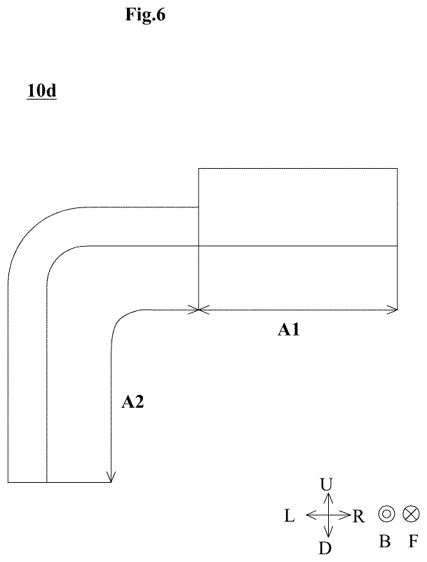

A multilayer substrate 10d according to a fourth modified example of an example embodiment of the present invention is described below with reference to the drawings. FIG. 5 is an exploded perspective view of the multilayer substrate 10d. FIG. 6 is a rear view of the multilayer substrate 10d.

The multilayer substrate 10d differs from the multilayer substrate 10 in that the multilayer substrate 10d includes a first area A1 and a second area A2. More specifically, in the first area A1, the radiation conductor layer 16 and the second ground conductor layers 30a to 30d are provided. In the second area A2, the signal conductor layer 20 and the first ground conductor layer 28 are provided. The second area A2 has a strip shape extending along the signal conductor layer 20. The first area A1 is not bent. The second area A2 is bent. Other components of the multilayer substrate 10d are the same or substantially the same as those of the multilayer substrate 10, and thus are not described. The multilayer substrate 10d has the same or substantially the same advantageous effects as the multilayer substrate 10.

### OTHER EXAMPLE EMBODIMENTS

A multilayer substrate according to the present invention is not limited to the multilayer substrates 10 and 10a to 10d according to example embodiments of the present invention, and may be changed within the scope of the present invention. Components of the multilayer substrates 10 and 10a to 10d may be combined as appropriate.

The inter-layer connection conductors v11 and v12 may extend through multiple insulator layers.

When viewed in the downward direction, a connection portion at which the branched conductor layer 22 and the electric current path R are connected does not have to overlap the second ground conductor layers 30a to 30d.

When viewed in the downward direction, a portion of the branched conductor layer 22 may overlap the second ground conductor layers 30a to 30d.

When viewed in the downward direction, the branched conductor layer 22 may overlap the radiation conductor layer 16.

The branched conductor layer 22 is not required to have a linear shape. The branched conductor layer 22 may have, for example, a circular shape or a square shape.

The multilayer substrates 10 and 10a to 10d according to example embodiments of the present invention may include a feeding point P2 in addition to the feeding point P1. In this case, an electromagnetic-field vibration direction of a high-frequency signal fed at the feeding point P2 differs from an electromagnetic-field vibration direction of a high-frequency signal fed at the feeding point P1.

In the second area A2 of the multilayer substrate 10d, a third ground conductor layer may be provided on the signal conductor layer 20.

Each of the multilayer substrates 10 and 10a to 10d according to example embodiments of the present invention may include at least one of the second ground conductor layers 30a to 30d.

Each of the second ground conductor layers 30a to 30d is not required to have a loop shape surrounding the radiation conductor layer 16. Each of the second ground conductor layers 30a to 30d may include, for example, multiple conductor layers arranged at intervals on a loop-shaped track surrounding the radiation conductor layer 16 when viewed in the downward direction.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer substrate, comprising:
a multilayer body;
a radiation conductor layer;
a first ground conductor layer;
a second ground conductor layer;
an electric current path; and
a branched conductor layer; wherein
the multilayer body includes a plurality of insulator layers laminated along a Z-axis;
the radiation conductor layer is in or on the multilayer body;
the first ground conductor layer is in or on the multilayer body, overlaps the radiation conductor layer when viewed in a negative direction of the Z-axis, and extends in the negative direction of the Z-axis from the radiation conductor layer;
the second ground conductor layer is in or on the multilayer body, does not overlap the radiation conductor layer when viewed in the negative direction of the Z-axis, and extends in a positive direction of the Z-axis from the first ground conductor layer;
when viewed in the negative direction of the Z-axis, no ground conductor layer other than the first ground conductor layer is located between the radiation conductor layer and the second ground conductor layer;
the electric current path is in or on the multilayer body, and connected to the radiation conductor layer;
the branched conductor layer is in or on the multilayer body, extends in the negative direction of the Z-axis from the second ground conductor layer, and extends away from the electric current path; and
when viewed in the negative direction of the Z-axis, at least a portion of the branched conductor layer overlaps the second ground conductor layer.

2. The multilayer substrate according to claim 1, wherein, when viewed in the negative direction of the Z-axis, a connection portion at which the branched conductor layer and the electric current path are connected overlaps the second ground conductor layer.

3. The multilayer substrate according to claim 1, wherein, when viewed in the negative direction of the Z-axis, an entirety or substantially an entirety of the branched conductor layer overlaps the second ground conductor layer.

4. The multilayer substrate according to claim 1, wherein, when viewed in the negative direction of the Z-axis, the branched conductor layer does not overlap the radiation conductor layer.

5. The multilayer substrate according to claim 1, wherein
the electric current path includes an inter-layer connection conductor;
the inter-layer connection conductor extends through at least one of the plurality of insulator layers along the Z-axis; and
the branched conductor layer is connected to the inter-layer connection conductor.

6. The multilayer substrate according to claim 1, wherein, when viewed in the negative direction of the Z-axis, the second ground conductor layer has a loop shape surrounding the radiation conductor layer.

7. The multilayer substrate according to claim 1, wherein
the electric current path includes a signal conductor layer;
the signal conductor layer is in or on the multilayer body, extends in the negative direction of the Z-axis from the radiation conductor layer, and extends in the positive direction of the Z-axis from the first ground conductor layer; and
a distance between the signal conductor layer and the first ground conductor layer along the Z-axis is shorter than a distance between the signal conductor layer and the radiation conductor layer along the Z-axis.

8. The multilayer substrate according to claim 1, wherein the branched conductor layer includes an open stub.

9. The multilayer substrate according to claim 1, wherein the branched conductor layer includes a short stub.

10. The multilayer substrate according to claim 1, wherein the multilayer body has a rectangular or substantially rectangular plate shape.

11. The multilayer substrate according to claim 1, wherein each of the plurality of insulator layers includes polyimide or liquid crystal polymer.

12. The multilayer substrate according to claim 1, wherein the radiation conductor layer and the first ground conductor layer define a patch antenna.

13. The multilayer substrate according to claim 7, wherein the signal conductor layer includes a first portion extending in a first direction orthogonal or substantially orthogonal to the Z-axis and a second portion extending in a second direction orthogonal or substantially orthogonal to the Z-axis and the first direction.

14. The multilayer substrate according to claim 1, further comprising an external electrode in an opening in the first ground conductor layer.

15. The multilayer substrate according to claim 1, wherein the branched conductor layer has a linear shape.

16. The multilayer substrate according to claim 1, wherein the second ground conductor layer has an angular-C shape.

17. The multilayer substrate according to claim 1, wherein a plurality of the second ground conductor layers are provided on the plurality of insulator layers.

18. The multilayer substrate according to claim 13, wherein the first portion is provided on a different insulator layer of the plurality of insulator layers than the second portion.
